(19) United States
(12) Patent Application Publication
(10) Pub. No.: US 2007/0052107 A1
(43) Pub. Date: Mar. 8, 2007

(54) MULTI-LAYERED STRUCTURE AND FABRICATING METHOD THEREOF AND DUAL DAMASCENE STRUCTURE, INTERCONNECT STRUCTURE AND CAPACITOR

(76) Inventors: Cheng-Ming Weng, Hsinchu County (TW); Miao-Chun Lin, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,272

(22) Filed: Sep. 5, 2005

(51) Int. Cl. H01L 23/48

(52) U.S. Cl. 257/774

(57) ABSTRACT

A dual damascene structure comprising a substrate, a dielectric layer, a metal hard mask layer, a protection layer and a conductive layer is provided. The substrate has a conductive area. The dielectric layer is disposed on the substrate. The metal hard mask layer is disposed on the dielectric layer. The protection layer is disposed on the metal hard mask layer. A trench is disposed in the protection layer, the metal hard mask layer and a part of the dielectric layer. An opening is disposed in the dielectric layer under the trench. The opening exposes the conductive area. The conductive layer is disposed in the trench and the opening.

### BACKGROUND OF THE INVENTION

1. Field of the Invention

The present invention relates to a semiconductor structure and fabricating method thereof. More particularly, the present invention relates to a multi-layered structure and a fabricating method thereof as well as a dual damascene structure, interconnect structure and capacitor.

2. Description of the Related Art

With an increase in the level of integration of integrated circuits, the number of metal interconnect needed increases. Thus, a design having two or more metal layer has gradually become the norm in the fabrication of many types of integrated circuits. However, as the degree of integration of the integrated circuits continues to rise, it is increasingly difficult to increase the production yield or the reliability of the metal interconnects.

A damascene process is a method of fabricating metal interconnects that includes etching a trench in a dielectric layer and depositing a metal substance into the trench to form the interconnect. In the damascene process, there is no need to perform an etching operation to introduce a hard-to-etch metal such as copper into a semiconductor device. Furthermore, due to the difficulties in etching copper in semiconductor production processes, copper conductive lines are fabricated mostly using the damascene process instead of the conventional etching process.

In general, the damascene process includes forming a metal hard mask layer on the dielectric layer before etching out the trench or the opening. The metal hard mask layer is a titanium nitride (TiN) layer, for example. Thereafter, an etching operation is carried out. However, the fluorine-containing gaseous etchant often reacts with the titanium nitride in the etching operation to for a layer of titanium fluoride (TiFₓ) on the surface of the metal hard mask layer. The titanium fluoride layer frequently causes abnormal conduction, leakage or short circuit conditions in the device. Moreover, for most film layers fabricated using titanium nitride, for example, the anti-reflection layer of the interconnect structure and the upper electrode of the metal-insulator-metal (MIM) capacitor, the foregoing problem is also encountered with high frequencies.

### SUMMARY OF THE INVENTION

Accordingly, at least one objective of the present invention is to provide a multi-layered structure. A titanium-containing layer of the multi-layered structure has a metal oxide layer disposed thereon for preventing a fluoride compound from forming on the titanium-containing layer in the fabrication process.

At least another objective of the present invention is to provide a fabricating method of the multi-layered structure that utilizes a metal oxide layer on top of a titanium-containing layer to serve as a protection layer for preventing any titanium fluoride compound from forming over the titanium-containing layer.

At least another objective of the present invention is to provide a dual damascene structure such that a metal hard mask layer in the dual damascene structure has a protection layer disposed thereon for preventing fluoride compound from forming on the metal hard mask layer in the fabrication process.

At least another objective of the present invention is to provide an interconnect structure such that an anti-reflection layer of the interconnect structure has a protection layer disposed thereon for preventing fluoride compound from forming on the anti-reflection layer in the fabrication process.

At least another objective of the present invention is to provide a capacitor such that a second electrode in the upper area of the capacitor has a protection layer disposed thereon for preventing fluoride compound from forming on the second electrode in the fabrication process.

To achieve these and other advantages and in accordance with the purpose of the invention, as embodied and broadly described herein, the invention provides a multi-layered structure. The multi-layered structure comprises a titanium-containing layer and a metal oxide layer. The metal oxide layer is disposed on the titanium-containing layer.

According to the aforementioned multi-layered structure in the embodiment of the present invention, the metal oxide layer is fabricated using titanium oxide (TiO), tantalum oxide (TaO) or aluminum oxide (Al₂O₃), for example.

According to the aforementioned multi-layered structure in the embodiment of the present invention, the metal oxide layer has a thickness between about 10 Å˜300 Å, for example.

The present invention also provides a method of fabricating a multi-layered structure. First, a titanium-containing layer is provided. Then, a metal layer is formed on the titanium-containing layer. Thereafter, an oxidation process is performed to oxidize the metal layer into a metal oxide layer.

According to the aforementioned method of fabricating a multi-layered structure in the embodiment of the present invention, the metal layer is fabricated using titanium (Ti), tantalum (Ta) or aluminum (Al).

According to the aforementioned method of fabricating a multi-layered structure in the embodiment of the present invention, the oxidation process is carried out by passing oxygen through a plasma to oxidize the metal layer, for example.

The present invention also provides a dual damascene structure. The dual damascene structure comprises a substrate, a dielectric layer, a metal hard mask layer, a protection layer and a conductive layer. The substrate has a conductive area. The dielectric layer is disposed on the substrate. The metal hard mask layer is disposed on the dielectric layer. The protection layer is disposed on the metal hard mask layer. A trench is disposed in the protection layer, the metal hard mask layer and a part of the dielectric layer. An opening is disposed in the dielectric layer under the trench. The opening exposes the conductive area. In addition, a conductive layer is disposed in the trench and the opening.

According to the aforementioned dual damascene structure in the embodiment of the present invention, the metal hard mask layer is fabricated using titanium nitride, for example.

According to the aforementioned dual damascene structure in the embodiment of the present invention, the protection layer is a metal oxide layer, for example.

According to the aforementioned dual damascene structure in the embodiment of the present invention, the metal oxide layer is fabricated using titanium oxide, tantalum oxide or aluminum oxide, for example.

According to the aforementioned dual damascene structure in the embodiment of the present invention, the protection layer has a thickness between about 10 Å˜300 Å.

According to the aforementioned dual damascene structure in the embodiment of the present invention, the conductive layer is fabricated using copper, for example.

According to the aforementioned dual damascene structure in the embodiment of the present invention, the dual damascene structure may further include a barrier layer disposed between the substrate and the dielectric layer.

According to the aforementioned dual damascene structure in the embodiment of the present invention, the barrier layer is fabricated using silicon-carbon nitride (SiCN), silicon carbide (SiC) or silicon nitride (SiN), for example.

The present invention also provides an interconnect structure. The interconnect structure comprises a substrate, an anti-reflection layer, a protection layer, a dielectric layer and a plug. The substrate has a conductive area. The anti-reflection layer is disposed on the conductive area. The protection layer is disposed on the anti-reflection layer. The dielectric layer is disposed on the substrate. The plug is disposed in the dielectric layer in connection with the protection layer.

According to the aforementioned interconnect structure in the embodiment of the present invention, the anti-reflection layer is fabricated using titanium nitride, for example.

According to the aforementioned interconnect structure in the embodiment of the present invention, the protection layer is a metal oxide layer, for example.

According to the aforementioned interconnect structure in the embodiment of the present invention, the metal oxide layer is fabricated using titanium oxide, tantalum oxide or aluminum oxide, for example.

According to the aforementioned interconnect structure in the embodiment of the present invention, the protection layer has a thickness between about 10 Å˜300 Å, for example.

According to the aforementioned interconnect structure in the embodiment of the present invention, the conductive area is an aluminum (Al) conductive line, for example.

The present invention also provides a capacitor. The capacitor comprises a first electrode, a second electrode, a protection layer and a dielectric layer. The second electrode is disposed above the first electrode. The protection layer is disposed on the second electrode. The dielectric layer is disposed between the first electrode and the second electrode.

According to the aforementioned capacitor in the embodiment of the present invention, the second electrode is fabricated using titanium nitride, for example.

According to the aforementioned capacitor in the embodiment of the present invention, the protection layer is a metal oxide layer, for example.

According to the aforementioned capacitor in the embodiment of the present invention, the metal oxide layer is fabricated using titanium oxide, tantalum oxide or aluminum oxide, for example.

According to the aforementioned capacitor in the embodiment of the present invention, the protection layer has a thickness between about 10 Å˜300 Å, for example.

According to the aforementioned capacitor in the embodiment of the present invention, the first electrode is fabricated using a metal, for example.

According to the aforementioned capacitor in the embodiment of the present invention, the dielectric layer is a multi-layered dielectric layer, for example.

According to the aforementioned capacitor in the embodiment of the present invention, the multi-layered dielectric layer is an oxide/nitride/oxide composite layer, for example.

In the present invention, the metal hard mask layer of the dual damascene structure has a protection layer disposed thereon. In the process of performing an etching operation to form a plug opening, the metal hard mask layer is prevented from directly contacting and reacting with fluorine containing etchant to form a layer of fluoride compound. Thus, short circuit and leakage current problems can be avoided.

Furthermore, a protection layer is disposed on the anti-reflection layer inside the interconnect structure in the present invention. In the process of performing an etching operation to form a plug opening, the anti-reflection layer is prevented from directly contacting and reacting with fluorine containing etchant to form a layer of fluoride compound. Similarly, short circuit and leakage current problems can be avoided.

Similarly, a protection layer is disposed on the second electrode of a capacitor in the present invention to prevent the formation of a layer of fluoride compound on the second electrode.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A and 1B are schematic cross-sectional views showing the steps for fabricating a multi-layered structure according to one embodiment of the present invention.

FIG. 2 is a schematic cross-sectional view of a dual damascene structure according to one embodiment of the present invention.

FIG. 3 is a schematic cross-sectional view of an interconnect structure according to one embodiment of the present invention.

FIG. 4 is a schematic cross-sectional view of a metal-insulator-metal capacitor according to one embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

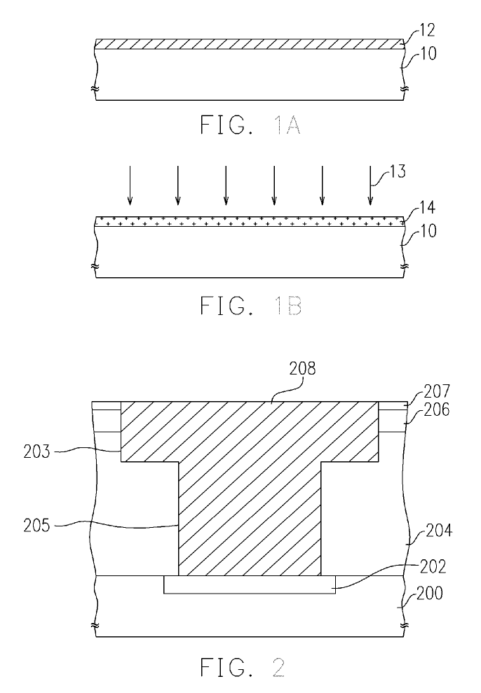

FIGS. 1A and 1B are schematic cross-sectional views showing the steps for fabricating a multi-layered structure according to one embodiment of the present invention. As shown in FIG. 1A, a titanium-containing layer 10 such as a titanium nitride layer is provided. Then, a metal layer 12 is formed on the titanium-containing layer 10. The metal layer 12 is fabricated using titanium, tantalum or aluminum, for example. Thereafter, as shown in FIG. 1B, an oxidation process 13 for oxidizing the metal layer 12 into a metal oxide layer 14 is carried out by passing oxygen through plasma. In the following, the multi-layered structure according to the present invention is applied to the process of fabricating dual damascene structures, interconnect structures and metal-insulator-metal (MIM) capacitors for preventing the formation of unwanted fluoride compound.

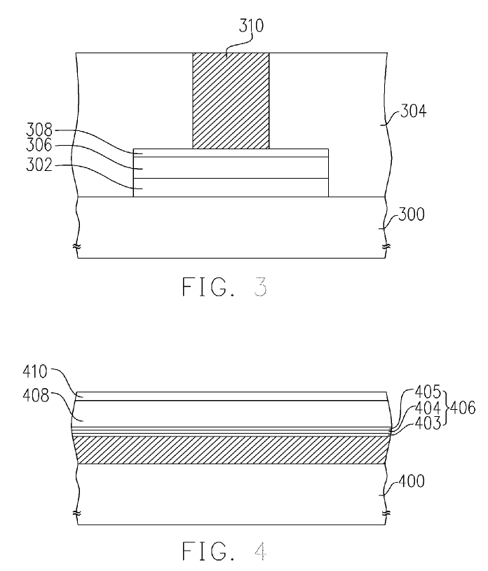

FIG. 2 is a schematic cross-sectional view of a dual damascene structure according to one embodiment of the present invention. As shown in FIG. 2, a substrate 200 having a conductive area 202 is provided. The conductive area 202 is a copper wire or other semiconductor device, for example. A dielectric layer 204 is disposed on the substrate 200. The dielectric layer 204 is fabricated using a low dielectric constant material, a porous low dielectric constant material or common dielectric material, for example. In another embodiment, a barrier layer (not shown) may also be disposed between the substrate 200 and the dielectric layer 204. The barrier layer can be fabricated using silicon-carbon nitride, silicon carbide or silicon nitride, for example. The purpose of forming the barrier layer is to prevent any oxidation in the exposed portion in the process of fabricating the conductive line if the conductive area 202 is a copper line. Then, a metal hard mask layer 206 is formed over the dielectric layer 204. The metal hard mask layer 206 is fabricated using titanium nitride, for example. Thereafter, a protection layer 207 is disposed on the metal hard mask layer 206. The protection layer 207 is a metal oxide layer, for example. The protection layer 207 is fabricated using titanium oxide, tantalum oxide or aluminum oxide, for example. The protection layer 207 has a thickness between about 10 Å˜300 Å, preferably a thickness around 70 Å.

It should be noted that the method of fabricating the protection layer 207 includes forming a metal layer, for example, a titanium, a tantalum or an aluminum layer (not shown) over the metal hard mask layer 206. Then, oxygen is passed through plasma to oxidize the metal layer into a titanium oxide, a tantalum oxide or an aluminum oxide layer. Alternatively, the protection layer 207 can be formed by directly depositing titanium oxide, tantalum oxide or aluminum oxide material on the metal hard mask layer 206.

As shown in FIG. 2, a trench 203 runs down the protection layer 207 and the metal hard mask layer 206 and a portion of the dielectric layer 204. The dielectric layer 204 underneath the trench 203 has an opening 205. The opening 205 exposes the conductive area 202. In addition, the conductive layer 208 is disposed inside the trench 203 and the opening 205. The conductive layer 208 is fabricated using copper, for example. It should be noted that the protection layer 207 prevents the metal hard mask layer 206 from reacting with the fluorine-containing etchant (for example, titanium fluoride) to form a fluoride compound on the metal hard mask layer 206 in the etching process for forming the trench 203 and the opening 205. Thus, the problems of having a short circuit or some current leaks are minimized.

FIG. 3 is a schematic cross-sectional view of an interconnect structure according to one embodiment of the present invention. As shown in FIG. 3, a substrate 300 having a conductive area 302 thereon is provided. The conductive area 302 is an aluminum conductive line, for example. An anti-reflection layer 306 is disposed on the conductive area 302. The anti-reflection layer 306 is fabricated using titanium nitride, for example. A protection layer 308 is disposed on the anti-reflection layer 306. The protection layer 308 is a metal oxide layer fabricated using titanium oxide, tantalum oxide or aluminum oxide, for example. The protection layer 308 has a thickness between about 10 Å˜300 Å, preferably the thickness is around 70 Å. A dielectric layer 304 is disposed on the substrate 300. A plug 310 is disposed in the dielectric layer 304 and connected to the protection layer 308. The plug 310 is fabricated using a metal, for example.

Similarly, the method of fabricating the protection layer 308 includes forming a metal layer, for example, a titanium, a tantalum or an aluminum layer (not shown) over the anti-reflection layer 306. Then, oxygen is passed through plasma to oxidize the metal layer into a titanium oxide, a tantalum oxide or an aluminum oxide layer. Alternatively, the protection layer 308 can be formed by directly depositing titanium oxide, tantalum oxide or aluminum oxide material on the anti-reflection layer 306.

FIG. 4 is a schematic cross-sectional view of a metal-insulator-metal capacitor according to one embodiment of the present invention. As shown in FIG. 4, an electrode 402 is disposed on a substrate 400. The electrode 402 is a metal layer, for example. Another electrode 408 is disposed above the former electrode 402. The electrode 408 is fabricated using titanium nitride, for example. A protection layer 410 is disposed on the electrode 408. The protection layer 410 is a metal oxide layer including titanium oxide, tantalum oxide or aluminum oxide, for example. The protection layer 410 has a thickness between about 10 Å˜300 Å, but preferable a thickness around 70 Å. A dielectric layer 406 is disposed between the electrode 402 and the electrode 408. The dielectric layer 406 is a multi-layered dielectric layer comprising a silicon oxide layer 403, a silicon nitride layer 404 and another silicon oxide layer 405, for example. Since the protection layer 410 is formed using the aforementioned method, a detailed description is omitted.

In summary, the dual damascene structure, the interconnect structure and the capacitor in the present invention all have a protection layer formed over the metal hard mask layer or anti-reflection layer, which are fabricated using titanium nitride material. Therefore, in the process of etching out the plug opening or performing a subsequent etching operation, the fluorine-containing etchant is prevented for reacting with the metal hard mask layer or the anti-reflection layer to form a titanium fluoride compound layer thereon. In other words, problems such as short circuiting or current leaks can be avoided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A multi-layered structure, comprising:
a titanium-containing layer; and
a metal oxide layer disposed on the titanium-containing layer.

2. The multi-layered structure of claim 1, wherein the material constituting the metal oxide layer includes titanium oxide (TiO), tantalum oxide (TaO) or aluminum oxide (Al₂O₃).

3. The multi-layered structure of claim 1, wherein the metal oxide layer has a thickness between about 10 Å˜300 Å.

4. A method of forming a multi-layered structure, comprising the steps of:
providing a titanium-containing layer;
forming a metal layer on the titanium-containing layer; and
performing an oxidation process to oxidize the metal layer into a metal oxide layer.

5. The method of claim 4, wherein the material constituting the metal layer includes titanium (Ti), tantalum (Ta) or aluminum (Al).

6. The method of claim 4, wherein the oxidation process includes passing oxygen into plasma to transform the metal layer into a metal oxide layer.

7. A dual damascene structure, comprising:
a substrate having a conductive area;
a dielectric layer disposed on the substrate;
a metal hard mask layer disposed on the dielectric layer;
a protection layer disposed on the metal hard mask layer, wherein the protection layer, the metal hard mask layer and a portion of the dielectric layer have a trench, and the dielectric layer underneath the trench has an opening that exposes the conductive area; and
a conductive layer disposed inside the trench and the opening.

8. The dual damascene structure of claim 7, wherein the material constituting the metal hard mask layer includes titanium nitride (TiN).

9. The dual damascene structure of claim 7, wherein the protection layer includes a metal oxide layer.

10. The dual damascene structure of claim 9, wherein the material constituting the metal oxide layer includes titanium oxide, tantalum oxide or aluminum oxide.

11. The dual damascene structure of claim 7, wherein the protection layer has a thickness between about 10 Å˜300 Å.

12. The dual damascene structure of claim 7, wherein the material constituting the conductive layer includes copper.

13. The dual damascene structure of claim 7, wherein the structure further includes a barrier layer disposed between the substrate and the dielectric layer.

14. The dual damascene structure of claim 13, wherein the material constituting the barrier layer includes silicon-carbon nitride (SiCN), silicon carbide (SiC) or silicon nitride (SiN).

15. An interconnect structure, comprising:
a substrate having a conductive area thereon;
an anti-reflection layer disposed on the conductive area;
a protection layer disposed on the anti-reflection layer;
a dielectric layer disposed on the substrate; and
a plug disposed in the dielectric layer in connection with the protection layer.

16. The interconnect structure of claim 15, wherein the material constituting the anti-reflection layer includes titanium nitride.

17. The interconnect structure of claim 15, wherein the protection layer include a metal oxide layer.

18. The interconnect structure of claim 17, wherein the material constituting the metal oxide layer includes titanium oxide, tantalum oxide or aluminum oxide.

19. The interconnect structure of claim 15, wherein the protection layer has a thickness between about 10 Å˜300 Å.

20. The interconnect structure of claim 15, wherein conductive area includes an aluminum conductive line.

21. A capacitor, comprising:
a first electrode;
a second electrode disposed above the first electrode;
a protection layer disposed on the second electrode; and
a dielectric layer disposed between the first electrode and the second electrode.

22. The capacitor of claim 21, wherein material constituting the second electrode includes titanium nitride.

23. The capacitor of claim 21, wherein the protection layer includes a metal oxide layer.

24. The capacitor of claim 23, wherein the material constituting the metal oxide layer includes titanium oxide, tantalum oxide or aluminum oxide.

25. The capacitor of claim 21, wherein the protection layer has a thickness between about 10 Å˜300 Å.

26. The capacitor of claim 21, wherein the material constituting the first electrode includes a metal.

27. The capacitor of claim 21, wherein the dielectric layer includes a multi-layered dielectric layer.

28. The capacitor of claim 27, wherein the multi-layered dielectric layer includes an oxide/nitride/oxide composite layer.
